(19) United States
(12) Patent Application Publication
(10) Pub. No.: US 2008/0122445 A1
(43) Pub. Date: May 29, 2008

(54) FIXTURE FOR ANALYZING THIN FLEXIBLE ELECTRONIC DEVICE

(75) Inventors: Yi-Ping Chou, Taipei City (TW); Yun-Tai Lai, Taichung City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: DENMOS TECHNOLOGY INC., Hsinchu (TW)

(21) Appl. No.: 11/754,376

(22) Filed: May 29, 2007

(30) Foreign Application Priority Data
Nov. 28, 2006 (TW) 95143922

(51) Int. Cl. G01R 31/02

(52) U.S. Cl. 324/537

(57) ABSTRACT

A fixture for facilitating failure analysis of a thin flexible electronic device is provided. The fixture includes a first stage and a second stage. The second stage covers the first stage from above, and the thin flexible electronic device is disposed between the first stage and the second stage. The second stage includes conductive pads, conductive paths, and pins. Positions of the conductive pads correspond to the electrical connection points of the thin flexible electronic device. The pins are disposed under the second stage, and the pins are respectively electrically connected to the conductive pads through the conductive paths.

### CROSS-REFERENCE TO RELATED APPLICATION

This application claims the priority benefit of Taiwan application serial no. 95143922, filed Nov. 28, 2006. All disclosure of the Taiwan application is incorporated herein by reference.

### BACKGROUND OF THE INVENTION

1. Field of the Invention

The present invention relates to a fixture. More particularly, the present invention relates to a fixture for a thin flexible electronic device.

2. Description of Related Art

In the modern days with flourishing science and technology, electronic devices are being designed to be light, thin, short, and small. With the improvement of semiconductor technology, liquid crystal displays with many advantageous features such as low power consumption, thin profile, light weight, high resolution, high color saturation, and long life have been developed, and are being widely used in electronic products used in our everyday life, such as notebook and desktop computers and liquid crystal televisions (LCD TV). Especially, integrated circuits (ICs) of the displays are indispensable elements of the liquid crystal displays.

Considering the need for various applications of the ICs, the IC package techniques for general ICs include chip on film (COF) package technique, tape carrier package (TCP) technique, etc. However, vendors of driving ICs for displays often encounter the problem of return of goods from clients, which normally happens in the following two situations. One situation is that after an IC vendor ships the completed chips to a panel manufacturer, the panel manufacturer finds out problems with the ICs during usage. At this time the panel manufacturer will return the ICs to the IC vendor directly. The other situation is that the panel manufacturer doesn't find out the problems with the ICs until the displays using the ICs are completed and shipped to consumers, and the consumers find out the problems with the driving ICs. However, in such a situation, the displays still need to be returned to the IC vendor for failure analysis.

When the IC vender receives an IC returned back by a client, in order to test the problem with the IC, it is necessary to recover the actual conditions in use for determining the problem. Different driving ICs are used for different panel sizes. Accordingly, the IC failure analysis method in conventional art may be described as follows. First, a corresponding printed wiring board (PWB) and a panel are removed. Next, the IC to be tested is connected to the PWB and the panel. Next, the failure analysis is performed to test various functions of the panel, such as the scanning frequency and the image display. However, such a method not only consumes time, but also costs a lot. In order to increase the testing speed, a good fixture plays an important role. In the conventional art, the Electrical Engineering Research Institute of Tsing Hua University proposed a fixture as shown in FIG. 1 in a thesis titled ‘Malfunction Analysis on Source Driving Integrated Elements of a Liquid Crystal Flat Panel Display Using Connection of Electron Beam Testing Machine with Extra-large Integrated Circuit Testing Machine’ in 2002. FIG. 1 is an exploded view of a fixture. The fixture includes a top holder 10, a printed circuit board (PCB) 20, a bottom holder 30, a conductive rubber layer 40, and a stage 60. The stage 60 has a groove 103, such that a chip 104 of the TCP 50 can be easily placed in the stage 60. However, the fixture has disadvantages as follows.

1. Pins 101 of the PCB 20 are located above the PCB 20, which not only makes the wiring difficult but also causes misconnection in use due to the disordered wiring.

2. A hole 102 is disposed in the PCB 20 for facilitating multi-layer inspection (EMMI) of the TCP 50 under test using an emission microscope during the test, however the fixture allows to conduct EMMI only on one side of the chip 104 of the TCP 50, while problems of the other side can not be inspected.

3. The TCP 50 is fixed to the stage 60 with screws. This may likely cause damage to the TCP 50. Besides, if the TCP 50 is not aligned properly, and needs to be moved, it is necessary to repeatedly screw and unscrew for removing and fixing, which is very inconvenient to the user.

In view of the above, how to resolve the above problems is an important issue for the IC manufacturers in the field.

### SUMMARY OF THE INVENTION

Accordingly, the present invention is directed to a fixture. The fixture is used to analyze a thin flexible electronic device, so as to facilitate the failure analysis, and to reduce the probability of failure during the failure analysis.

As embodied and broadly described herein, the present invention provides a fixture for analyzing a thin flexible electronic device. The fixture comprises a first stage and a second stage, wherein the second stage covers the first stage from above, such that the thin flexible electronic device is disposed between the second stage and the first stage. The second stage has a plurality of conductive pads, a plurality of conductive paths, and a plurality of pins. Positions of the conductive pads correspond to the electrical connection points of the thin flexible electronic device. The pins are disposed under the second stage, and the pins are electrically connected to the corresponding conductive pads through the conductive paths respectively.

In one embodiment of the present invention, the first stage of the fixture comprises a first hole, wherein a position of the first hole corresponds to the thin flexible electronic device. Besides, the first stage includes an aligning mark, wherein a position of the aligning mark corresponds to the thin flexible electronic device. Furthermore, the first stage includes a retaining mechanism for retaining the thin flexible electronic device at the position of the first stage. The retaining mechanism has pumping holes, wherein positions of the pumping holes correspond to the thin flexible electronic device. The second stage comprises a second hole, wherein a position of the second hole corresponds to the thin flexible electronic device.

To sum up, the present invention uses a fixture to reduce the time of the failure analysis process and to save more cost. Moreover, the fixture simplifies the wiring lines, so as to prevent unexpected failure due to misconnection of the lines. In addition, the user can adjust the aligning position of the thin flexible electronic device more easily.

In order to the make aforementioned and other objects, features and advantages of the present invention comprehensible, preferred embodiments accompanied with figures are described in detail below.

### BRIEF DESCRIPTION OF THE DRAWINGS

FIG. 1 is an exploded view of a conventional fixture.

FIG. 2 is an exploded view of a fixture according to a preferred embodiment of the present invention.

FIG. 3 shows a conductive rubber layer 41 according to a preferred embodiment of the present invention.

FIG. 4 shows a method of connecting a fixture to a thin flexible device for according to a preferred embodiment of the present invention.

### DESCRIPTION OF EMBODIMENTS

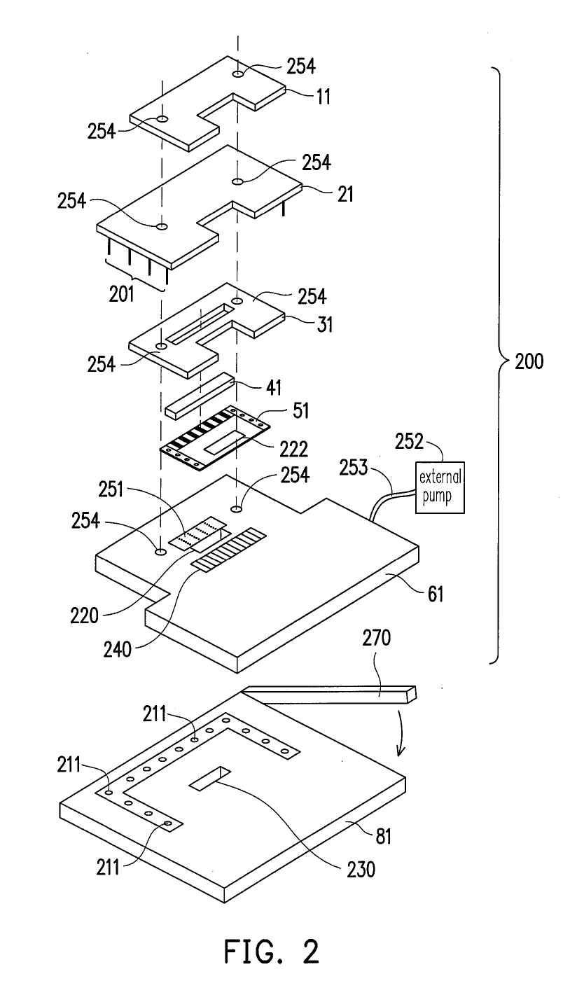

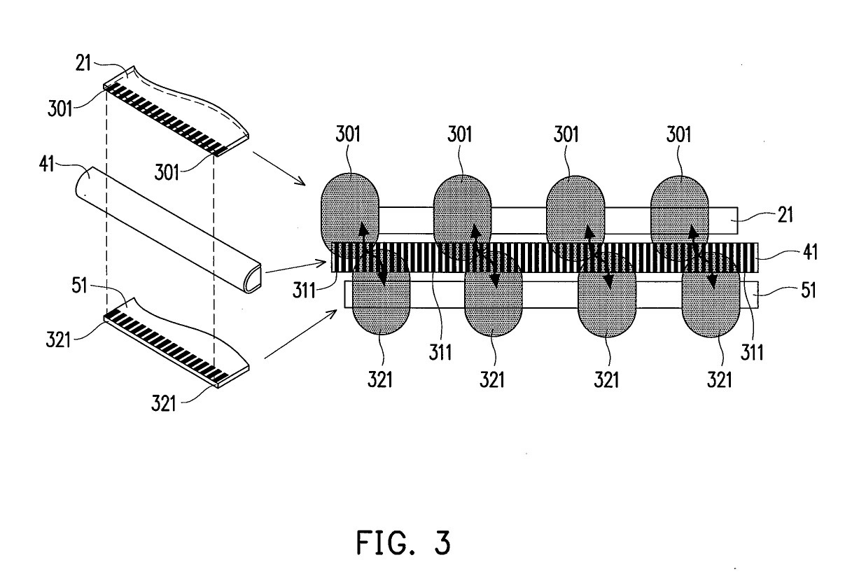

FIG. 2 is an exploded view of a fixture according to a preferred embodiment of the present invention. Referring to FIG. 2, the fixture 200 includes a top holder 11, a second stage 21, a bottom holder 31, a conductive rubber layer 41, and a first stage 61. The fixture 200 is used for analyzing a thin flexible electronic device 51. In this embodiment, the thin flexible electronic device 51 is comprised of, for example but not limited to, a COF. Alternatively, the thin flexible electronic device 51 can be other forms of packaged chips, for example, the TCP and the like. The top holder 11 of the fixture 200 covers the stage 21 from above, for fixing and protecting the stage 21. The bottom holder 31 is disposed between the stage 61 and the stage 21 for fixation and protection as well. The bottom holder 31 includes a conductive rubber layer 41, through which the stage 21 and the thin flexible electronic device 51 are electrically connected. The electrical connection thereof may be illustrated with reference to FIG. 3.

FIG. 3 shows a conductive rubber layer 41 according to a preferred embodiment of the present invention. Referring to FIGS. 2 and 3 together, the conductive rubber layer 41 is an elastic material for securely electrically connecting the stage 21 and the thin flexible electronic device 51. The conductive rubber layer 41 has a plurality of conductive wires 311, and the conductive wires 311, which are independent lines without electrically connecting with each other. A plurality of conductive pads 301 and a plurality of pins 201 are disposed on the bottom surface of the stage 21. In this embodiment, the stage 21 comprises, for example but not limited to, a printed circuit board (PCB). Alternatively, the stage 21 can be any plate with a circuit. In the internal electrical connection of the stage 21, each of the plurality of conductive pads 301 is electrically connected to one of the plurality of pins 201 respectively through the conductive paths (not shown). In the electrical connection of the stage 21 with the thin flexible electronic device 51, the conductive pads 301 are electrically connected to the electrical connection points 321 of the thin flexible electronic device 51 through the conductive wires 311. That is, the conductive pads 301 can be electrically connected to the corresponding electrical connection points 321 through the conductive rubber layer 41. Moreover, in order to securely bind the stage 21, the bottom holder 31, and the thin flexible electronic device 51 with the stage 61, a mechanism such as screws or a fastener can be used to fix the stage 21 on the stage 61. For example, screw holes 254 are designed for the screws to fix the stages.

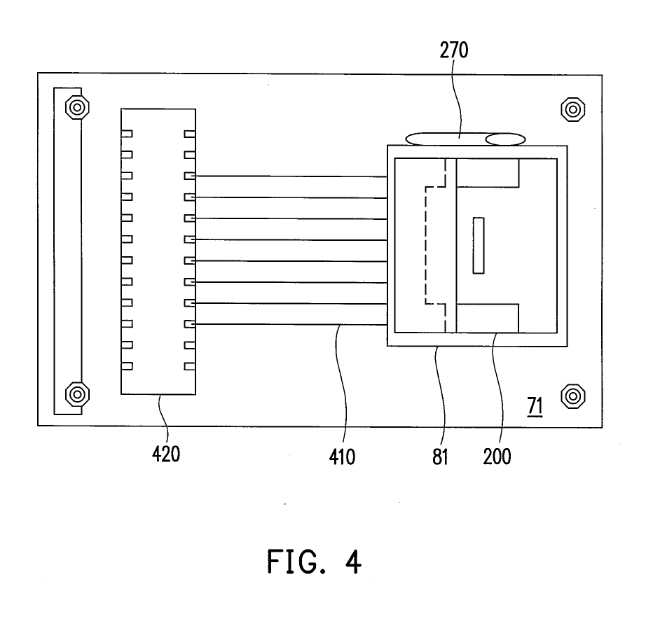

Referring to FIG. 2 again, it should be noted that the pins 201 of the stage 21 are extended downward, and positions of the pins 201 correspond to a plurality of jacks backs 211 in figures) of a seat 81 on a table 71 (shown in FIG. 4). When the pins 201 are inserted into the corresponding jacks 211, the seat 81 on the table 71 can securely clamp the pins 201 of the stage 21 by operating a holding lever 270, such that the stage 21 is firmly combined with the table 71. When the failure analysis on the thin flexible electronic device 51 is performed with the table 71, the stage 21 can be electrically connected to the jacks 211 of the table 71 through the pins 201. As additional wiring to the outside via the pins 201 is not required, the dazing lines are omitted, and the bench clean be maintained neat and clean. Also, unexpected failure in the failure analysis due to misconnection may be prevented.

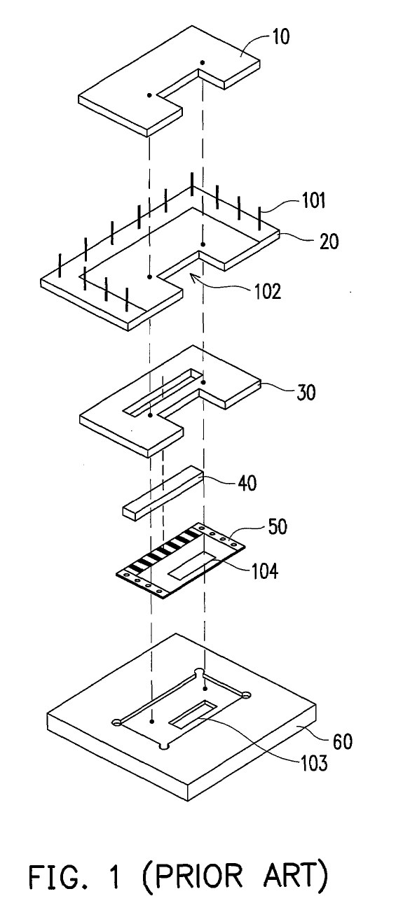

In another embodiment, the stage 61 further includes a hole 220. The hole 220 improves the groove 103 of FIG. 1 of the prior art. The groove 103 of FIG. 1 is used to position the chip conveniently. This embodiment improves the groove to the hole 220, which not only preserves the advantage that the chip 222 can be positioned conveniently, but also allows EMMI under the stage 61 during the failure analysis to detect whether misconnection exists in the chip 222. Certainly, persons of ordinary skill in the art can open a corresponding hole 230 in the table 71 to facilitate the EMMI, which is not described herein.

In another embodiment, the stage 61 has a mark 240 and a pumping hole 251. The mark 240 and the pumping hole 251 replace the method of fixing the thin flexible electronic device 51 to the stage 61 with the screws in the prior art. The mark 240 enables the user to easily adjust the aligning position of the thin flexible electronic device 51. Upon completion of the alignment, an external pump 252 is used to suck the air from the pumping hole 251 through a pipe 253, so as to fix the thin flexible electronic device 51 to the stage 61 according to the principle of pressure difference. It should be understood by persons of ordinary skill in the art that the position of the pumping hole 251 and the air-suction method of the external pump 252 can be modified according to actual requirements. Thus, the user can easily retain the thin flexible electronic device 51 at the stage 61. When the alignment is not proper, the external pump 252 is turned off to adjust the aligning position of the thin flexible electronic device 51. Besides, by using the fixing method of the external pump 252, the thin flexible electronic device 51 is further protected from being damage due to removal and fixing of the screws.

FIG. 4 shows a method for connecting the fixture 200 to the thin flexible electronic device during the failure analysis according to a preferred embodiment of the present invention. Referring to FIG. 4, prior to performing the failure analysis on the thin flexible electronic device 51, the thin flexible electronic device 51 is placed in the fixture 200 first. The fixture 200 wraps the thin flexible electronic device 51 like a box. The fixture 200 makes the electrical connection points of the thin flexible electronic device 51 electrically connect to the pins 201. The thin flexible electronic device 51 can be rapidly placed into the fixture 200. Next, the fixture 200 is positioned on the seat 81 of the table 71, so as to combine the pins 201 of the fixture 200 with the table 71. The seat 81 is electrically connected to a field programmable gate array (FPGA) 420 on the table 71 through a PCB layout 410. Accordingly, the FPGA 420 can perform the failure analysis of the thin flexible electronic device 51 with the PCB layout 410, the seat 81 and the fixture 200. Even though the failure analysis according to this embodiment is implemented using the FPGA, persons of ordinary skill in the art would understand that the failure analysis may also be implemented using a complex programmable logic device (CPLD) or a programmable logic device (PLD), etc., which shall be construed to be within the scope of the present invention. Thus, the use of expensive electron beam testing machine as in the case of the prior art may be avoided, and therefore the cost may be effectively reduced.

To sum up, the fixture 200 of the present invention has at least the following advantages:

1. The pins 201 face downward and need not be connected to the external circuit using wires. Thus, the wiring lines may be simplified, and the unexpected failure due to misconnection of the lines may be prevented.

2. The holes 254 are arranged to facilitate the detection of the line connection state for both sides of the chip 222 using the EMMI. Thus, the problems associated with dead angles as in the case of the prior art may be prevented.

3. The mark 240 is arranged to facilitate the alignment of the thin flexible electronic device 51. Thus, the unexpected failure due to improper alignment may be prevented.

4. The external pump 252 is used to effectively hold the thin flexible electronic device 51 on the stage 61. Thus, the risk of damaging the thin flexible electronic device 51 caused by the screws as in the case of the prior art may be resolved. Furthermore, the position of the thin flexible electronic device 51 can be easily adjusted.

5. The fixture 200 allows using the FPGA, the CPLD or the PLD to perform the failure analysis. Thus, the use of expensive electron beam testing machine for performing the failure analysis as in the case of the prior art may be effectively prevented. Therefore, the cost may be effectively reduced.

It will be apparent to persons of ordinary skill in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A fixture, suitable for facilitating failure analysis of a thin flexible electronic device, comprising:
a first stage; and
a second stage, covering the first stage from above, wherein the thin flexible electronic device is disposed between the second stage and the first stage, and wherein the second stage comprises:
a plurality of conductive pads positioned corresponding to electrical connection points of the thin flexible electronic device;
a plurality of conductive paths; and
a plurality of pins, disposed under the second stage, wherein the pins are electrically connected to the corresponding conductive pads through the conductive paths respectively.

2. The fixture as claimed in claim 1, wherein the first stage comprises a first hole positioned corresponding to the thin flexible electronic device.

3. The fixture as claimed in claim 1, wherein the first stage comprises an aligning mark positioned corresponding to the thin flexible electronic device.

4. The fixture as claimed in claim 1, wherein the first stage comprises a retaining mechanism for retaining the thin flexible electronic device at a position on the first stage.

5. The fixture as claimed in claim 4, wherein the retaining mechanism comprises a plurality of pumping holes positioned corresponding to the thin flexible electronic device.

6. The fixture as claimed in claim 1, wherein the second stage comprises a second hole positioned corresponding to the thin flexible electronic device.

7. The fixture as claimed in claim 1, wherein the second stage is a printed circuit board.

8. The fixture as claimed in claim 7, further comprising a top holder for covering the second stage from above.

9. The fixture as claimed in claim 1, further comprising a conductive rubber layer disposed between the first stage and the second stage, wherein the conductive pads are respectively electrically connected to the corresponding electrical connection points of the thin flexible electronic device via the conductive rubber layer.

10. The fixture as claimed in claim 1, wherein the first stage and the second stage are fixed using screws.

11. The fixture as claimed in claim 1, wherein the thin flexible electronic device includes a chip-on-film (COF).

12. The fixture as claimed in claim 1, wherein the thin flexible electronic device includes a tape carrier package (TCP).
